(19) United States
(12) Patent Application Publication
(10) Pub. No.: US 2026/0313800 A1
(43) Pub. Date: Oct. 8, 2026

(54) MULTIPURPOSE COUPLING MECHANISM

(71) Applicant: MELLANOX TECHNOLOGIES, LTD., Yokneam (IL)

(72) Inventors: Dimitry Basin, Kiriat Ata (IL); Ben Ahuvi, Yokneam (IL)

(21) Appl. No.: 19/173,143

(22) Filed: Apr. 8, 2025

(51) Int. Cl. H05K 1/14

(52) U.S. Cl. CPC H05K 1/141; H05K 2201/10265; H05K 2201/10409

(57) ABSTRACT

Examples of a multipurpose coupling mechanism are disclosed. In an example, an apparatus includes a PCB, a top cover at a top surface of the PCB, a bottom plate at a bottom surface of the PCB, at least one coupling mechanism that includes a captive screw and a spring around the captive screw, wherein the at least one coupling mechanism is configured to press the top cover, the PCB, and the bottom plate together, and expose threads of the captive screw at the bottom plate for attachment to a base board.

### FIELD

The present disclosure relates to coupling mechanisms, for example, coupling mechanisms for printed circuit board (PCB) modules.

### BACKGROUND

Data centers include racks of computers and each rack typically includes multiple adapter cards that are installed in the rack like drawers in a cabinet. The adapter cards may include servers, switches, firewalls, storage, and power supplies. Additionally, each one of the adapter cards in a rack may include multiple different components. For example, a component of an adapter card may include a PCB module that includes integrated circuit (IC) devices dedicated to some particular function. In order to enhance the serviceability of an adapter card, the PCB module of an adapter card may include screws that enable the PCB module to be easily attached to and removed from the swappable card. While it is necessary to provide a way to attach a PCB module to a swappable card, space can be very limited within each swappable card with each component of the swappable card competing for a portion of the limited space.

### GENERAL DESCRIPTION

Examples of a multipurpose coupling mechanism are disclosed. In an example, an apparatus includes a PCB, a top cover at a top surface of the PCB, a bottom plate at a bottom surface of the PCB, at least one coupling mechanism that includes a captive screw and a spring around the captive screw, wherein the at least one coupling mechanism is configured to press the top cover, the PCB, and the bottom plate together, and expose threads of the captive screw at the bottom plate for attachment to a base board.

In an example, the captive screw passes through an opening in the top cover, an opening in the PCB, and a treaded opening in the bottom plate.

In an example, the top cover includes an opening, the opening in the top cover having a first portion and a second portion, wherein a diameter of the first portion of the opening is greater than a diameter of the second portion of the opening, the opening in the top cover includes a spring hard stop at a transition between the first portion of the opening and the second portion of the opening, the diameter of first portion of the opening accommodates a shank of the captive screw and the spring, and the diameter of the second portion of the opening accommodates the shank of the captive screw but not the spring.

In an example, the at least one coupling mechanism includes four coupling mechanisms.

An example of an apparatus is disclosed. The apparatus includes a PCB, a bottom plate at a bottom surface of the PCB, a top cover at a top surface of the PCB; at least one captive screw having a screw head, a shank, and threads, and at least one spring around the shank of the captive screw, the top cover including an opening having a first portion and a second portion, wherein a diameter of the first portion of the opening is greater than a diameter of the second portion of the opening, and wherein the diameter of first portion of the opening accommodates the shank and the spring and the diameter of the second portion of the opening accommodates the shank but not the spring, the bottom plate including a threaded opening wherein the threads of the captive screw mate with the threaded opening of the bottom plate, and the captive screw positioned within the opening of the top cover, within an opening in the PCB, and within the threaded opening of the bottom plate.

In an example, the opening in the top cover includes a spring hard stop at a transition between the first portion of the opening and the second portion of the opening.

In an example, the diameter of the first portion of the opening in the top cover matches a diameter of the spring.

In an example, the opening in the top cover includes a spring hard stop at a transition between the first portion of the opening and the second portion of the opening, and the diameter of the first portion of the opening in the top cover matches a diameter of the spring.

In an example, the opening in the top cover includes a screw head hard stop that extends from a top surface of the top cover and that is configured to abut the screw head of the captive screw.

In an example, the opening in the top cover includes a spring hard stop at a transition between the first portion of the opening and the second portion of the opening, the diameter of the first portion of the opening in the top cover matches a diameter of the spring, and the opening in the top cover includes a screw head hard stop that extends from a top surface of the top cover.

In an example, the threads of the captive screw are configured to attach to a base board.

In an example, the shank of the captive screw includes a first portion and a second portion, wherein a diameter of the first portion of the shank is greater than a diameter of the second portion of the shank, and the first portion of the shank is about a third of the length of the shank and the second portion of the shank is about two-thirds of the length of the shank.

In an example, the threads have a length of about 1.5-2.5 mm.

In an example, the shank of the captive screw includes a first portion and a second portion, wherein a diameter of the first portion of the shank is greater than a diameter of the second portion of the shank, the first portion of the shank is about a third of the length of the shank and the second portion of the shank is about two-thirds of the length of the shank, and the threads have a length of about 1.5-2.5 mm.

In an example, the opening in the top cover includes a spring hard stop at a transition between the first portion of the opening and the second portion of the opening, the diameter of the first portion of the opening in the top cover matches a diameter of the spring, and the shank of the captive screw includes a first portion and a second portion, wherein the first portion of the shank is about a third of the length of the shank and the second portion of the shank is about two-thirds of the length of the shank.

Another example of an apparatus is disclosed. The apparatus includes a captive screw for a PCB module that includes a PCB, a bottom plate, and a top cover, the captive screw including a screw head, a shank configured to pass through an opening in the top cover and an opening in the PCB, and having a first portion with a first diameter and a second portion with a second diameter, wherein the first diameter is greater than the second diameter, and threads, wherein the threads are configured to mate with threads of an opening in the bottom plate and to engage a base board upon passing through the opening in the bottom plate.

In an example, The apparatus of claim 16, wherein the first portion of the shank is about a third of the length of the shank and the second portion of the shank is about two-thirds of the length of the shank.

In an example, the threads have a length of about 1.5-2.5 mm.

In an example, the first portion of the shank is about a third of the length of the shank and the second portion of the shank is about two-thirds of the length of the shank, and the threads have a length of about 1.5-2.5 mm.

In an example, the shank includes a spring attachment feature.

Other aspects in accordance with the disclosure will become apparent from the following detailed description, taken in conjunction with the accompanying drawings, illustrated by way of example of the principles of the disclosure.

### BRIEF DESCRIPTION OF THE DRAWINGS

FIG. 1A is a perspective view of a PCB module that includes a top cover, a PCB, a bottom plate, and four captive screws and corresponding springs.

FIG. 1B is a perspective view of the PCB module from FIG. 1A in which the PCB module is attached to a base board.

FIG. 2 is a top view of the PCB module shown in FIGS. 1A and 1B.

FIG. 3 is a bottom view of the PCB module shown in FIGS. 1A, 1B and 2 that shows the bottom plate and a portion of the PCB that is not covered by the bottom plate.

FIG. 4 depicts a side view of one of the captive screws that is included in a coupling mechanism of a PCB module that includes a top cover, a PCB, and a bottom plate.

FIG. 5A is a perspective sectional view of the PCB module shown in FIGS. 1A, 1B, 2, and 3 at section A-A (FIG. 2).

FIG. 5B is a perspective sectional view of the PCB module similar to FIG. 5A.

FIG. 6A is a straight on sectional view of the PCB module shown in FIG. 5A in which the PCB module is not attached to a base board.

FIG. 6B is a straight on section view of the PCB module of FIG. 6A in which the PCB module is attached to the base board.

FIG. 7 is a perspective view of a bottom plate.

FIG. 8 is a conceptual illustration of a computer system configured to implement one or more aspects of the various embodiments.

FIG. 9 illustrates a computer system, according to at least one embodiment.

FIG. 10 is a block diagram that schematically illustrates a computing system in accordance with an embodiment that is described herein.

Throughout the description, similar reference numbers may be used to identify similar elements.

### DETAILED DESCRIPTION

It will be readily understood that the components of the examples as generally described herein and illustrated in the appended figures could be arranged and designed in a wide variety of different configurations. Thus, the following more detailed description of various examples, as represented in the figures, is not intended to limit the scope of the present disclosure, but is merely representative of various examples. While the various aspects of the examples are presented in drawings, the drawings are not necessarily drawn to scale unless specifically indicated.

The present disclosure may be embodied in other specific forms without departing from its spirit or essential characteristics. The described embodiments are to be considered in all respects only as illustrative and not restrictive. The scope of the disclosure is, therefore, indicated by the appended claims rather than by this detailed description. All changes which come within the meaning and range of equivalency of the claims are to be embraced within their scope.

Reference throughout this specification to features, advantages, or similar language does not imply that all of the features and advantages that may be realized with the present disclosure should be or are in any single example. Rather, language referring to the features and advantages is understood to mean that a specific feature, advantage, or characteristic described in connection with an example is included in at least one example of the present disclosure. Thus, discussions of the features and advantages, and similar language, throughout this specification may, but do not necessarily, refer to the same example.

Furthermore, the described features, advantages, and characteristics of the disclosure may be combined in any suitable manner in one or more embodiments. One skilled in the relevant art will recognize, in light of the description herein, that the disclosure can be practiced without one or more of the specific features or advantages of a particular embodiment. In other instances, additional features and advantages may be recognized in certain examples that may not be present in all examples of the disclosure.

Reference throughout this specification to “one example”, “an example”, or similar language means that a particular feature, structure, or characteristic described in connection with the indicated example is included in at least one embodiment of the present disclosure. Thus, the phrases “in one example”, “in an example”, and similar language throughout this specification may, but do not necessarily, all refer to the same embodiment.

Many types of computers are designed to incorporate one or more expansion cards that provide the computer with additional capabilities, such as enhanced video or gaming performance, accelerated video capture, the ability to connect to a network, and/or the ability to connect to a musical instrument, to name a few. An expansion card, which also is referred to as an adapter card, an add-on card, or an expansion board, is a card-based processing subsystem that typically includes a printed circuit board (PCB) that is adapted to connect to an expansion slot on the motherboard of a given computer.

To provide the microprocessor(s), memory, and other elements of the chipset of a card-based processing subsystem with the appropriate supply voltage and current, the power components of the card-based processing subsystem are usually mounted directly on the PCB portion of the card-based processing subsystem. For example, large capacitors, inductors, and power MOSFETs (metal-oxide-semiconductor field-effect transistors) are generally mounted adjacent to the processor(s) and memory chips on the PCB portion of the processing subsystem. Power is then delivered from these power components to the microprocessor(s), memory, and other elements of the chipset via a power distribution network that is made up of electrically conductive interconnects formed on the surface of, and within, the layers of the PCB, such as metallic traces, plated vias, and power and ground planes.

A PCB module that is installed within an adapter card may include a PCB that is sandwiched between a top cover and a bottom plate. Often times, the PCB module includes a first set of screws that is dedicated to holding the top plate, the PCB, and the bottom plate together and a second set of screws that is dedicated to attaching the PCB module to a base board of the swappable card. A set of screws to hold the PCB module together and another set of screws to attach the PCB module to a base board contribute to the overall footprint of the PCB module, which must fit within the limited space of a swappable card.

It has been realized that a coupling mechanism that includes a captive screw and a spring can be used to both hold components of a PCB module together and to attach the PCB module to a base board of a broader computing system such as an adapter card. The spring is configured to maintain the screw's position and ensures a secure fit. In an example, a coupling mechanism is configured to press the top cover, the PCB, and the bottom plate of a PCB module together and to expose threads of the captive screw at the bottom plate for attachment to a base board to achieve a PCB size reduction while maintaining functionality and stability. A PCB module that utilizes a coupling mechanism as described herein does not need one set of screws dedicated to holding components of the PCB module together and another set of screws dedicated to attaching the PCB module to a base board. Rather, the coupling mechanism utilizes a single captive screw and corresponding spring to both hold components of the PCB module together and to attach the PCB module to a base board of a broader computer system such as a swappable card. In one example, a PCB module includes four captive screws and corresponding springs to both hold components of a PCB module together and to attach the PCB module to a base board of a broader computer system such as a swappable card making it easy to assemble and disassemble. Thus, the reduced number of screws can result in space savings for the PCB module. For example, the footprint of a PCB module can be reduced in size relative to a PCB module that has different sets of screws dedicated to different functions. To reduce the dimensions of the PCB module, threads were added to the bottom part, allowing the mounting screws to remain captive after assembly. The spring beneath the screw head provides enough pressure to securely hold all mechanical parts together, making them a single, solid unit.

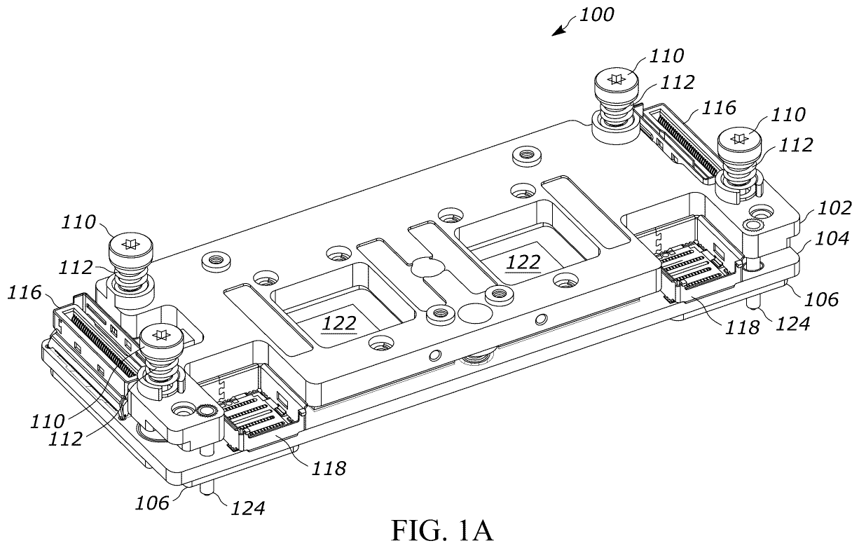

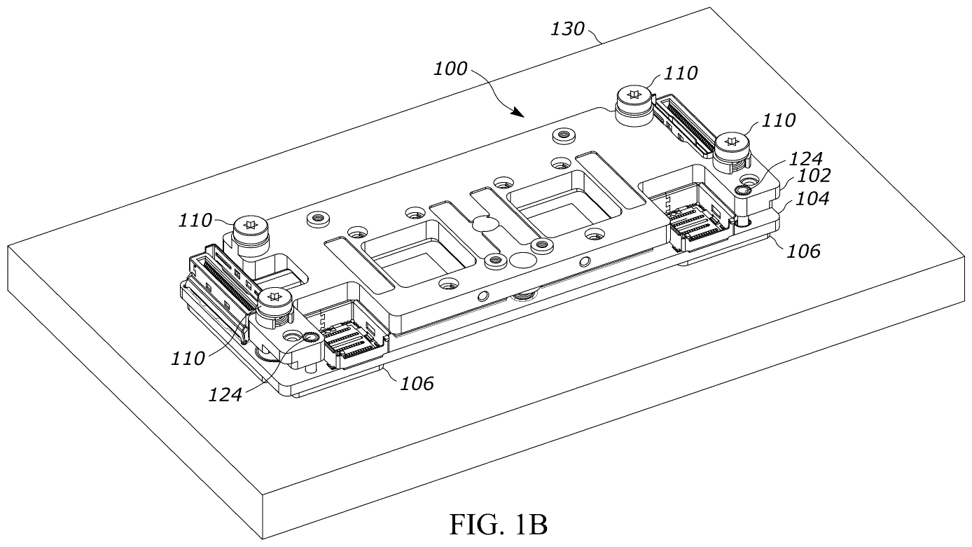

FIG. 1A is a perspective view of a PCB module 100 that includes a top cover 102, a PCB 104, a bottom plate 106, and four captive screws 110 and corresponding springs 112. As is described herein, the captive screws and springs form part of the coupling mechanisms that both hold components of the PCB module together and attach the PCB module to a base board of a broader computer system such as a swappable card. In the example of FIG. 1A, the captive screws are in a captive position as is described below.

In the example of FIG. 1A, the PCB 104 of the PCB module 100 includes a substrate and attached electronic components as is known in the field. The PCB may include an IC device, or IC devices, (not shown) and interface components (e.g., data connectors 116 and/or power connectors 118) that are attached to a substrate of the PCB. Some interface components of the PCB such as the data connectors 116 and the power connectors 118 are visible in FIG. 1A but other electronic components (e.g., IC devices) of the PCB are not visible due to the cover plate.

A PCB is used to electrically connect electronic components using conductive pathways, or traces, etched from metal sheets. In many electronic systems, one or more very large-scale integrated circuit (“VLSI”) components is coupled to a host system printed circuit board (“PCB”). Such VLSI components may include, for example, central processing unit (“CPU) devices and graphics processing unit (“GPU”) devices. The PCB may hold at least one processing circuitry. The processing circuitry may comprise hardware, such as an application specific integrated circuit (ASIC). The processing circuitry may comprise an ASIC and/or may be capable of performing as a central processing unit (CPU), a graphics processing unit (GPU), a network interface controller (NIC), a data processing unit (DPU), quantum processing units (QPUs), a plurality of parallel processing units (PPUs), and application-specific integrated circuits (ASICs) or any other computing device in which with data is received and/or transmitted. QPUs configured to perform one or more operations associated with a quantum algorithm. In some embodiments, each of the one or more QPUs may include a plurality of qubits and the one or more QPUs may be in communication with each other via a quantum channel. In some embodiments, each of the plurality of qubits may include local qubits, global qubits, and/or synchronization qubits. In some embodiments, the local qubits of each QPU may be configured to perform the one or more operations associated with the quantum algorithm on the QPU that the local qubits are associated with. Other non-limiting examples of the processing circuitry include an Integrated Circuit (IC) chip, a Central Processing Unit (CPU), a Graphics Processing Unit (GPU), a microprocessor, a Field Programmable Gate Array (FPGA), a collection of logic gates or transistors, resistors, capacitors, inductors, diodes, or the like. It should be appreciated that any appropriate type of electrical or optical component or collection of electrical or optical components may be suitable for inclusion in the processing circuitry. Numerous example embodiments will be described below in which a semiconductor package is mounted within a through hole of a PCB. Although PCBs having certain types and form factors appear in the drawings and the discussion, it should be noted that the illustrated and described types and form factors are provided by way of example only. Persons having skill in the art and having reference to this disclosure will readily appreciate that the same or similar apparatus and techniques may also be employed with PCBs having other types and form factors. For example, in some embodiments, the PCB to which the semiconductor package is mounted may comprise an add-in card, such as a PCIe card, that is configured to be coupled to a system board or motherboard of a host system. In other embodiments, the PCB to which the semiconductor package is mounted may be the system board or motherboard of the host system itself. Moreover, the system board or the motherboard may be associated with any type of host system. For example, the PCB may comprise the system board in a multi-node rack-mounted server in a data center, or it may comprise the motherboard of a workstation, desktop, laptop, or mobile device. Other embodiments are also possible.

In the example of FIG. 1A, the top cover 102 of the PCB module is a metal piece that is directly adjacent to a top surface of the PCB 104 and that is shaped to cover at least a portion of the PCB. The top cover may include features that provide space for components of the PCB such as the data connectors 116 and the power connectors 118. For example, the features may be openings in the top cover that accommodate the data connectors 116 and the power connectors 118. The top cover may include additional features 122, such as cavities or openings that promote cooling of components on the PCB, for example, air cooling and/or liquid cooling of IC devices on the PCB. In an example, the top cover is a metal such as aluminum, copper, or steel with a thickness of around 1-7 mm.

In the example of FIG. 1A, the bottom plate 106 of the PCB module 100 is a metal piece that is directly adjacent to a bottom surface of the PCB 104 and that is shaped to provide structural support to at least a portion of the PCB. For example, the bottom plate is a metal such as aluminum or steel with a thickness of around 1 mm. The bottom plate provides structural stiffness to the PCB module and protects the PCB from damage that could result from attachment to a base board. The bottom plate is often referred to as a stiffener.

The PCB module 100 also includes alignment posts 124 that are used to properly align the PCB module on a base board. The alignment posts may be embedded within concentric openings in the top cover 102, the PCB 104, and the bottom plate 106. In an example, the base board includes alignment receptors, such as holes in the base board, that have complimentary spacing to the spacing of the alignment posts of the PCB module. Seating of the alignment posts of the PCB module within the alignment receptors of a base board sets the position of the PCB module on the base board.

FIG. 1B is a perspective view of the PCB module 100 from FIG. 1A in which the PCB module is attached to a base board 130. In the example of FIG. 1B, the captive screws 110 are engaged with female receptors (not shown) of the base board and the screw head of each captive screw is abutted against a corresponding screw head hard stop of the top cover 102. Additionally, the alignment posts 124 are seated within alignment receptors in the base board and therefore portions below the bottom plate 106 are not visible in FIG. 1B. When the PCB module is attached to the base board, the bottom plate of the PCB module is in direct contact with at least a portion of the base board. The base board may be, for example, a frame or motherboard of a broader computing system, although the base board could be some other structure to which the PCB module is to be attached.

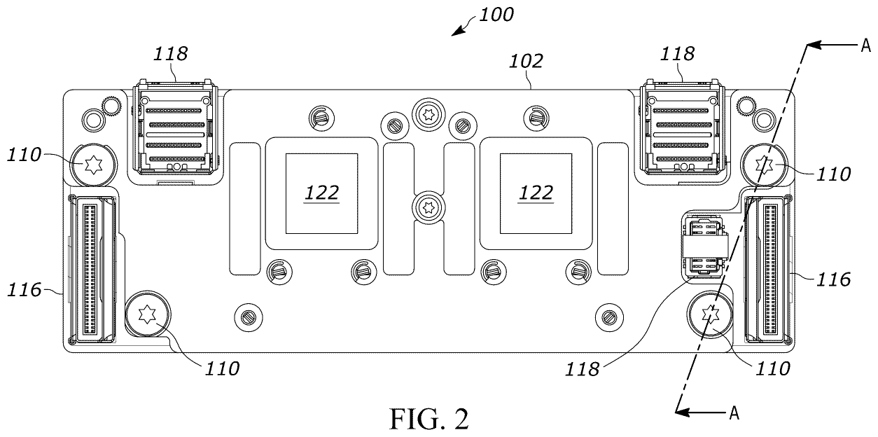

FIG. 2 is a top view of the PCB module 100 shown in FIGS. 1A and 1B. Elements visible in the top view of FIG. 2 include a top surface of the top cover 102, some components 116 and 118 of the PCB, openings 122 in the top cover, and four captive screws 110 that are located at four corners of the PCB module. Although the four captive screws are shown in particular locations, other locations of the captive screws are possible.

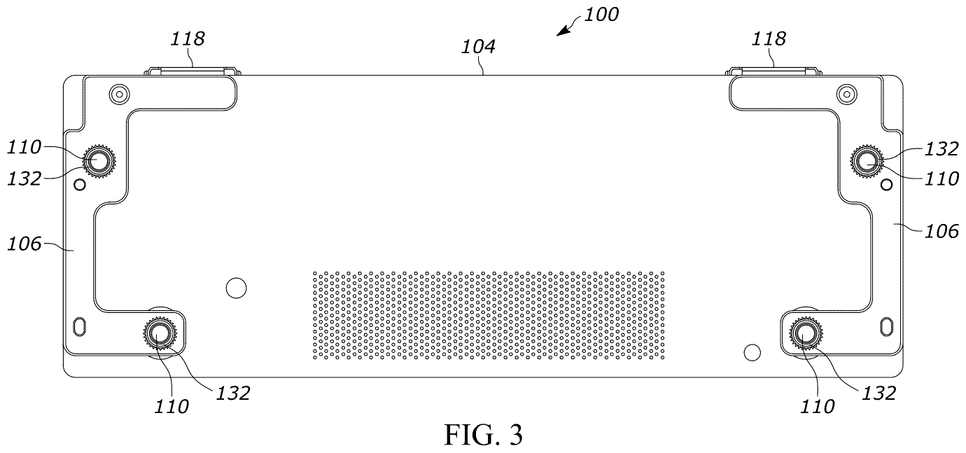

FIG. 3 is a bottom view of the PCB module 100 shown in FIGS. 1A, 1B and 2 that shows the bottom plate 106 and a portion of the PCB 104 that is not covered by the bottom plate. In the example of FIG. 3, the bottom plate includes two separate pieces at opposing ends of the PCB module but the bottom plate could include more than two pieces, or the bottom plate could be a single piece. As shown in FIG. 3, the bottom plate includes four openings 132 to receive the four captive screws 110. The four openings in the bottom plate are threaded openings that include threads that mate with the threads of the captive screws. Although in this example the bottom plate is in two pieces and each piece has a specific shape, other shapes of the bottom plate are possible.

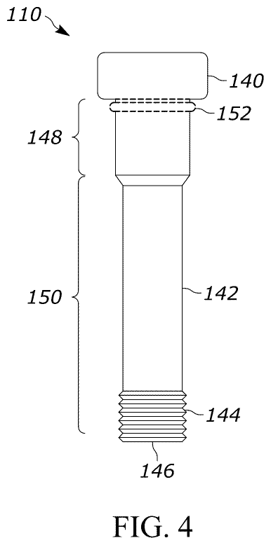

FIG. 4 depicts a side view of one of the captive screws 110 that is included in a coupling mechanism of a PCB module that includes a top cover, a PCB, and a bottom plate. The captive screw includes a screw head 140, a shank 142, threads 144, and a tip 146. The shank is configured to pass through an opening in a top cover and an opening in a PCB of a PCB module and the threads are configured to mate with threads of an opening in a bottom plate of the PCB module and to engage a base board upon passing through the opening in the bottom plate. The screw head includes a drive feature (not shown) such as a hex, slot, cross, or socket feature as is known in the field. The shank includes a first portion 148 and a second portion 150, in which the diameter of the first portion 148 is greater than the diameter of the second portion 150. Additionally, the first portion of the shank is about a third of the length of the shank and the second portion of the shank is about two-thirds of the length of the shank. In the example of FIG. 4, the first portion of the shank has a larger diameter to hold the spring securely in place while the second portion has a smaller diameter to correspond to allow for a small hole size in the PCB 104 and the bottom plate 106. In some examples, use of the term about with respect to example dimensions includes dimensions within ±20% of the dimension, within ±10% of the dimension, or within ±5% of the dimension.

In an example, the captive screw 110 has a length of 23.7 mm, the screw head 140 has a diameter of 7.5 mm, the first portion 148 of the shank 142 has a diameter of 4 mm, the second portion 150 of the shank 142 has a diameter of 2.5 mm, and the threads 144 have a length/depth in the range of 1.5-2.5 mm, and in one example a length/depth of 2 mm. Although some example dimensions of the captive screw are provided, the captive screw may have different dimensions. A feature of the captive screw is that the threaded portion of the shank has a wider diameter than the second portion of the shank, which enables the captive screw to be threaded through a complementary threaded opening in the bottom plate but not to pass back through the threaded opening in the bottom plate unless the captive screw is rotated.

In an example, the captive screw 110 has a spring attachment feature 152. For example, the upper end of the shank may have a bump or ring that helps to secure a spring in plate around the shank of the captive screw.

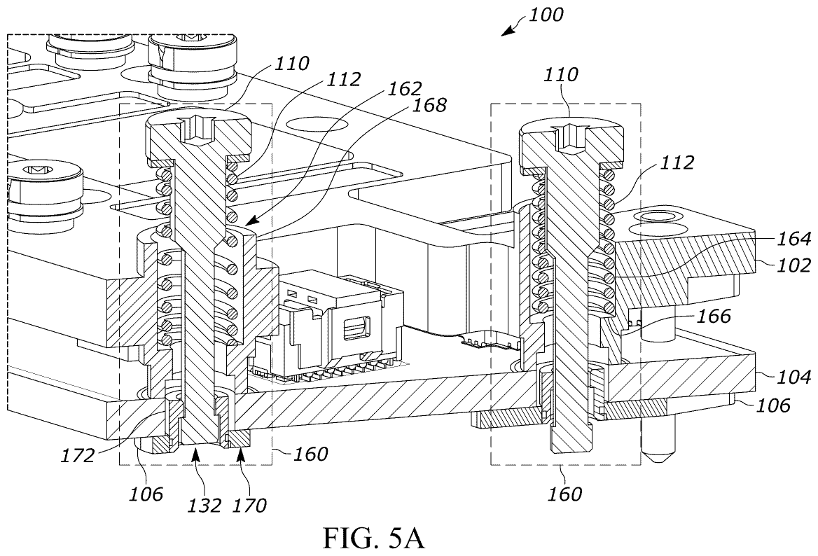

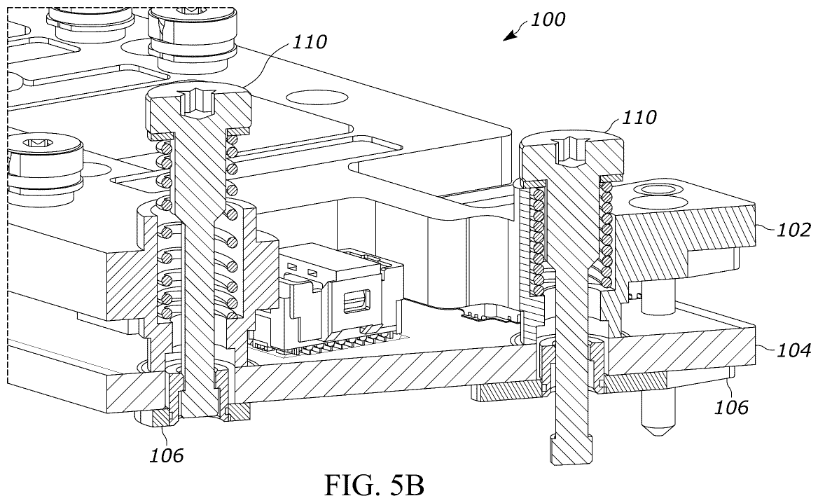

FIG. 5A is a perspective sectional view of the PCB module 100 shown in FIGS. 1A, 1B, 2, and 3 at section A-A (FIG. 2) that shows two coupling mechanisms 160 in which the captive screw 110 on the left side is in a threaded position and the captive screw 110 on the right side is in a captive position. Elements of the PCB module shown in FIG. 5A include the top plate 102, the PCB 104, the bottom plate 106, two captive screws 110, and two springs 112.

Elements of the top cover 102 of the PCB module 100 include, for each coupling mechanism 160, an opening 162 through the top cover that includes a spring housing 164, a spring hard stop 166, and a screw head hard stop 168. In the example of FIG. 5A, the spring housing 164 is a portion of the opening that is sized to match the spring 112. For example, the depth of the spring housing accommodates the spring in a compressed state and the diameter of the housing is just slightly larger than the diameter of the spring in an uncompressed state, e.g., ±0.5-2 mm. The spring hard stop 166 is a shelf formed by a difference in diameter of the opening 162 in the top cover in which the spring housing has a larger diameter than an adjacent segment of the opening.

Elements of the PCB 104 of the PCB module 100 include, for each coupling mechanism 160, an opening 170 that is big enough to pass the captive screw 110 without the need for rotation of the captive screw. For example, the diameter of a circular opening in the PCB is large enough to pass the threaded portion of a captive screw.

Elements of the bottom plate 106 of the PCB module 100 include threaded openings 132 that are configured to mate with the threads 144 of the captive screw 110. In the example of FIG. 5A, the bottom plate includes an extended structure 172 that includes threads configured to mate with the threads of the captive screw. In another example, the bottom plate has a uniform thickness with a planar top surface and a planar bottom surface and fewer threads than is the case in the example of FIG. 5A.

As indicated above, the two captive screws 110 of the corresponding coupling mechanisms 160 are shown in two different states in FIG. 5A. The captive screw on the left side of FIG. 5A has its threads engaged with the threads of the threaded opening 132 in the bottom plate 106. When the captive screw is in this state (threaded state), the spring 112 is at least partially compressed between the screw head 140 of the captive screw and the spring hard stop 166 of the spring housing 162. The compressed spring applies mechanical force to the captive screw and to the spring hard stop that presses the top cover 102, the PCB 104, and the bottom plate 106 together. In an example, the spring is designed such that the applied force in this state is enough to hold the top cover 102, the PCB 104, and the bottom plate 106 of the PCB module 100 securely together.

The captive screw 110 on the right side of FIG. 5A has its threads passed all the way through the threaded opening 132 in the bottom plate 106 such that the threads of the captive screw are exposed at the bottom plate for attachment to a base board. When the captive screw is in this state (captive state), the spring 112 is further compressed between the screw head 140 of the captive screw and the spring hard stop 166 of the spring housing 164. Because the captive screw will not pass back through the threaded opening in the bottom plate unless the captive screw is rotated, the compressed spring applies mechanical force to the captive screw and to the spring hard stop that presses the top cover 102, the PCB 104, and the bottom plate 106 together. Again, the spring is designed such that the applied force in this state is enough to hold the top cover 102, the PCB 104, and the bottom plate 106 of the PCB module 100 securely together. In an example, a coupling mechanism 160 is formed by elements that include the captive screw 110, the opening 162 in the top plate 102, the spring housing 164, the spring hard stop 166, the screw head hard stop 168, the opening 170 in the PCB 104, and the threaded opening 132 in the bottom plate 106. The elements of the coupling mechanism ensure that the top cover, the PCB, and the bottom plate are coupled to each other and enable the PCB module to be coupled to a base board.

FIG. 5B is a perspective sectional view of the PCB module 100 similar to FIG. 5A that shows the captive screw 110 on the left side in the threaded state similar to FIG. 5A and the captive screw of the right side in a fully down position. In particular, the captive screw on the left side of FIG. 5B has its threads engaged with the threads of the bottom plate the same as in FIG. 5A but the captive screw on the right side of FIG. 5B has its threads all the way passed through the threaded opening in the bottom plate and the screw head of the captive screw is abutted against the screw head hard stop 168 of the top cover 102. The captive screw is in this state when the captive screw is engaged with a female receptor (not shown) of a base board. When the captive screw is in this state (attached state), the force from the screw head of the captive screw on the top cover holds the top cover 102, the PCB 104, and the bottom plate 106 together and holds the PCB module 100 against the base board.

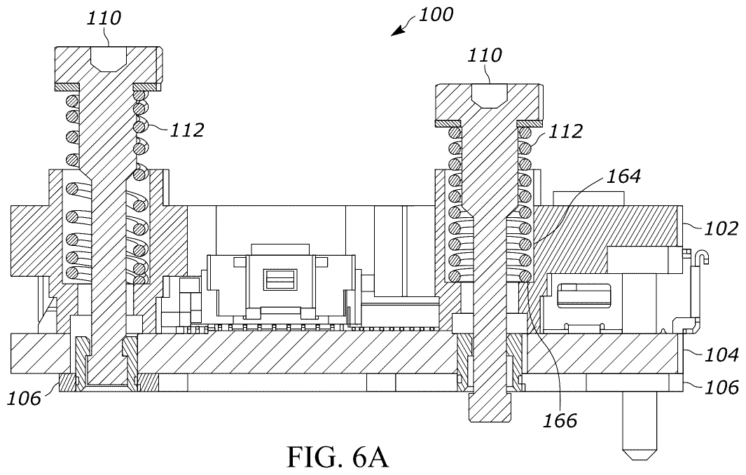

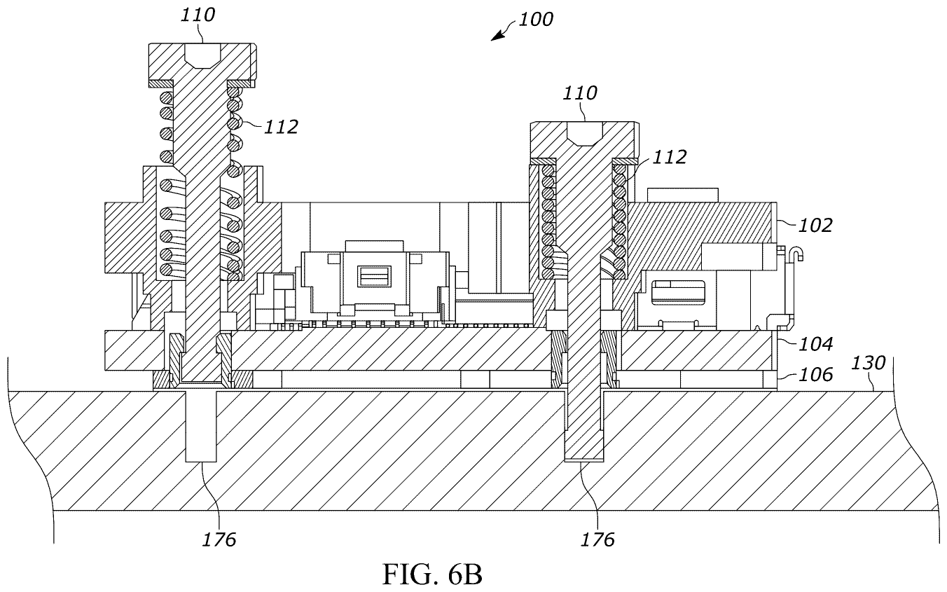

FIG. 6A is a straight on sectional view of the PCB module 100 shown in FIG. 5A in which the PCB module is not attached to a base board. In the example of FIG. 6A, the captive screw 110 on the left side is engaged with the threads of the bottom plate 106 (threaded state) and the captive screw on the right side has its threads up against the bottom plate (captive state). While in either of these two states, the coupling mechanisms hold the top cover 102, the PCB 104, and the bottom plate 106 of the PCB module together. In particular, force applied by the springs 112 against the captive screws and against the spring hard stops 166 of the spring housings 164 causes the top plate 102, the PCB 104, and the bottom plate 106 of the PCB module 100 to be pressed together. Thus, even when the PCB module is not attached to a base board, the PCB module is held together.

In operation, a PCB module is attached to a base board by screwing the captive screws of the PCB module into corresponding female receptors of the base board. For example, each captive screw is driven in a clockwise direction until the screw head hits the screw head hard stop and/or until the tip of the screw reaches an end of the female receptor in the base board.

FIG. 6B is a straight on section view of the PCB module 100 of FIG. 6A in which the PCB module is attached to the base board 130. In the example of FIG. 6B, for illustrative purposes, the captive screw 110 on the left side is not yet attached to the base board while the captive screw of the right side is attached to the base board. As shown in FIG. 6B, the captive screw on the left side has its threads still engaged with the threads of the bottom plate 106 while the captive screw on the right side has its threads engaged with threads of a female receptor 176 of the base board. The captive screw on the left side can be attached to the base board by pressing the captive screw towards the base board and rotating the screw in the clockwise direction.

When a captive screw is in the position as shown on the left side of FIG. 6B, the captive screw 110, the spring 112, and accompanying components of the corresponding coupling mechanism hold the top cover 102, the PCB 104, and the bottom plate 106 together and when a captive screw is in the position as shown on the right side of FIG. 6B, the captive screw, the spring, and the accompanying components of the corresponding coupling mechanism hold the top cover, the PCB, and the bottom plate together and the captive screw attaches the PCB module to the base board 130. Although only two coupling mechanisms are shown in FIGS. 6A and 6B, in an example, four captive screws of four coupling mechanisms would be attached to four corresponding female receptors in the base board. Mechanical forces supplied by the captive screws attached within the female receptors both hold the top plate 102, the PCB 104, and the bottom plate 106 of the PCB module 100 together and securely attach the PCB module to the base board 130.

Removal of the PCB module 100 from the base board 130 involves unscrewing the captive screws 110 from the female receptors 176 of the base board, which provides robustness, stability and ease of assembly and disassembly. Upon removal of the captive screws from the female receptors of the base board, the springs 112 will cause the captive screws to lift/move away from the base board but the threads of the captive screws will keep the captive screws from passing through the threaded openings in the bottom plate 106. Thus, the coupling mechanisms of the PCB module help to lift the captive screws out of the base board once unscrewed and the captive screws hold the top cover 102, the PCB 104, and the bottom plate 106 together after the PCB module 100 is detached from the base board.

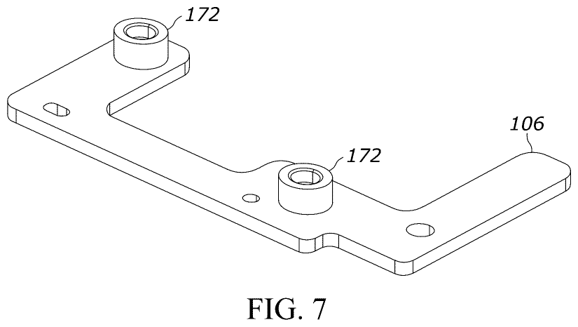

FIG. 7 is a perspective view of a bottom plate, in particular, the bottom plate 106 on the left side of bottom view of FIG. 3. The bottom plate includes the extended structures 172 that are configured to seat inside corresponding openings in the PCB. The extended structures of the bottom plate include threads configured to mate with the threads of the captive screw. In an example, the bottom plate includes a chamfered edge around the opening on the bottom side of the bottom plate.

In some common cases, a PCB module may include four coupling mechanisms for a total of four captive screws and corresponding springs. In an example, a captive screw is considered to be at a corner of the PCB module when the captive screw is within a corner region of the PCB module, where a corner region of the PCB module may be anywhere within one of four equally sized quadrants of the PCB module. In another example, a captive screw is within a corner region of the PCB module if the screw head is within three screw head diameters of the screw head from two sides of the PCB module.

In an example, a PCB module as disclosed herein includes a PCB, a bottom plate at a bottom surface of the PCB, a top cover at a top surface of the PCB, and at least one captive screw having a screw head, a shank, and threads, and at least one spring around the shank of the captive screw, the top cover including an opening having a first portion and a second portion, wherein a diameter of the first portion of the opening is greater than a diameter of the second portion of the opening, and wherein the diameter of first portion of the opening accommodates the shank and the spring and the diameter of the second portion of the opening accommodates the shank but not the spring, the bottom plate including a threaded opening wherein the threads of the captive screw mate with the threaded opening of the bottom plate, and the captive screw positioned within the opening of the top cover, within an opening in the PCB, and within the threaded opening of the bottom plate. The captive screw and spring are utilized to form a multipurpose coupling mechanism that both 1) holds the top cover, the PCB, and the bottom plate together, and 2) provides an easy way to attach the PCB module to a base board. The captive screw, the spring, the top plate, and the bottom plate of a coupling mechanism work together to ensure that constant pressure is applied to hold the top cover, the PCB, and the bottom plate together whether or not the PCB module is attached to a base board. The spring also helps to indicate when the captive screw is detached from the base board.

The term “coupling” or similar language is intended to encompass both direct and indirect connections, whether physical, electrical, mechanical, logical, or otherwise. The connection may involve direct physical contact, attachment, or engagement, or it may involve communication, interaction, or cooperation between the elements. The term coupling to is used broadly to include any form of association, linkage, or relationship that enables the desired functionality or cooperation between two claimed elements. The term “coupled to” is not limited to any specific type of connection and is intended to cover a range of possible configurations and implementations.

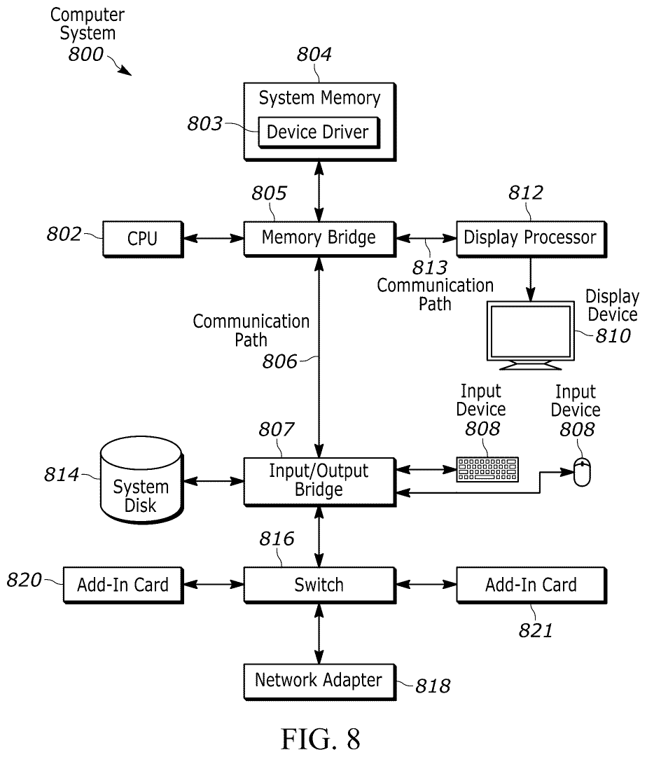

FIG. 8 is a conceptual illustration of a computer system 800 configured to implement one or more aspects of the various embodiments. As shown, system 800 includes a central processing unit (CPU) 802 and a system memory 804 communicating via a bus path that may include a memory bridge 805. CPU 802 includes one or more processing cores, and, in operation, CPU 802 is the master processor of system 100, controlling and coordinating operations of other system components. System memory 804 stores software applications and data for use by CPU 802. CPU 802 runs software applications and optionally an operating system. Memory bridge 805, which may be, e.g., a Northbridge chip, is connected via a bus or other communication path 806 (e.g., a HyperTransport link) to an I/O (input/output) bridge 807. I/O bridge 807, which may be, e.g., a Southbridge chip, receives user input from one or more user input devices 808 (e.g., keyboard, mouse, joystick, digitizer tablets, touch pads, touch screens, still or video cameras, motion sensors, and/or microphones) and forwards the input to CPU 802 via memory bridge 805.

A display processor 812 is coupled to memory bridge 805 via a bus or other communication path 113 (e.g., a PCI Express, Accelerated Graphics Port, or HyperTransport link); in one embodiment display processor 812 is a graphics subsystem that includes at least one graphics processing unit (GPU) and graphics memory. Graphics memory includes a display memory (e.g., a frame buffer) used for storing pixel data for each pixel of an output image. Graphics memory can be integrated in the same device as the GPU, connected as a separate device with the GPU, and/or implemented within system memory 804.

Display processor 812 periodically delivers pixels to a display device 810 (e.g., a screen or conventional CRT, plasma, OLED, SED or LCD based monitor or television). Additionally, display processor 812 may output pixels to film recorders adapted to reproduce computer generated images on photographic film. Display processor 812 can provide display device 810 with an analog or digital signal. In various embodiments, a graphical user interface is displayed to one or more users via display device 810, and the one or more users can input data into and receive visual output from the graphical user interface.

A system disk 814 is also connected to I/O bridge 807 and may be configured to store content and applications and data for use by CPU 802 and display processor 812. System disk 814 provides non-volatile storage for applications and data and may include fixed or removable hard disk drives, flash memory devices, and CD-ROM, DVD-ROM, Blu-ray, HD-DVD, or other magnetic, optical, or solid state storage devices.

A switch 816 provides connections between I/O bridge 807 and other components such as a network adapter 818 and various add-in cards 820 and 821. Network adapter 818 allows system 800 to communicate with other systems via an electronic communications network, and may include wired or wireless communication over local area networks and wide area networks such as the Internet.

Other components (not shown), including USB or other port connections, film recording devices, and the like, may also be connected to I/O bridge 807. For example, an audio processor may be used to generate analog or digital audio output from instructions and/or data provided by CPU 802, system memory 804, or system disk 814. Communication paths interconnecting the various components in FIG. 8 may be implemented using any suitable protocols, such as PCI (Peripheral Component Interconnect), PCI Express (PCI-E), AGP (Accelerated Graphics Port), HyperTransport, or any other bus or point-to-point communication protocol(s), and connections between different devices may use different protocols, as is known in the art.

In one embodiment, display processor 812 is configured as a processing subsystem that incorporates circuitry optimized for graphics and video processing, including, for example, video output circuitry, and constitutes a graphics processing unit (GPU). In another embodiment, display processor 812 is configured as a processing subsystem that incorporates circuitry optimized for general purpose processing. In yet another embodiment, display processor 812 may be integrated with one or more other system elements, such as the memory bridge 805, CPU 802, and I/O bridge 807 to form a system on chip (SoC). In still further embodiments, display processor 812 is omitted and software executed by CPU 802 performs the functions of display processor 812.

Pixel data can be provided to display processor 812 directly from CPU 802. In some embodiments, instructions and/or data representing a scene are provided to a render farm or a set of server computers, each similar to system 800, via network adapter 818 or system disk 814. The render farm generates one or more rendered images of the scene using the provided instructions and/or data. These rendered images may be stored on computer-readable media in a digital format and optionally returned to system 800 for display. Similarly, stereo image pairs processed by display processor 812 may be output to other systems for display, stored in system disk 814, or stored on computer-readable media in a digital format.

Alternatively, CPU 802 provides display processor 812 with data and/or instructions defining the desired output images, from which display processor 812 generates the pixel data of one or more output images, including characterizing and/or adjusting the offset between stereo image pairs. The data and/or instructions defining the desired output images can be stored in system memory 804 or graphics memory within display processor 812. In an embodiment, display processor 812 includes 3D rendering capabilities for generating pixel data for output images from instructions and data defining the geometry, lighting shading, texturing, motion, and/or camera parameters for a scene. Display processor 812 can further include one or more programmable execution units capable of executing shader programs, tone mapping programs, and the like.

Further, in other embodiments, CPU 802 or display processor 812 may be replaced with or supplemented by any technically feasible form of processing device configured to process data and execute program code. Such a processing device could be, for example, a central processing unit (CPU), a graphics processing unit (GPU), an application-specific integrated circuit (ASIC), a field-programmable gate array (FPGA), and so forth. In various embodiments any of the operations and/or functions described herein can be performed by CPU 802, display processor 812, or one or more other processing devices or any combination of these different processors.

CPU 802, render farm, and/or display processor 812 can employ any surface or volume rendering technique known in the art to create one or more rendered images from the provided data and instructions, including rasterization, scanline rendering REYES or micropolygon rendering, ray casting, ray tracing, image-based rendering techniques, and/or combinations of these and any other rendering or image processing techniques known in the art.

In other contemplated embodiments, system 800 may or may not include other elements shown in FIG. 8. System memory 804 and/or other memory units or devices in system 800 may include instructions that, when executed, cause the robot or robotic device represented by system 800 to perform one or more operations, steps, tasks, or the like.

It will be appreciated that the system shown herein is illustrative and that variations and modifications are possible. The connection topology, including the number and arrangement of bridges, may be modified as desired. For instance, in some embodiments, system memory 804 is connected to CPU 802 directly rather than through a bridge, and other devices communicate with system memory 804 via memory bridge 805 and CPU 802. In other alternative topologies display processor 812 is connected to I/O bridge 807 or directly to CPU 802, rather than to memory bridge 805. In still other embodiments, I/O bridge 807 and memory bridge 805 might be integrated into a single chip. The particular components shown herein are optional; for instance, any number of add-in cards or peripheral devices might be supported. In some embodiments, switch 816 is eliminated, and network adapter 818 and add-in cards 820, 821 connect directly to I/O bridge 807.

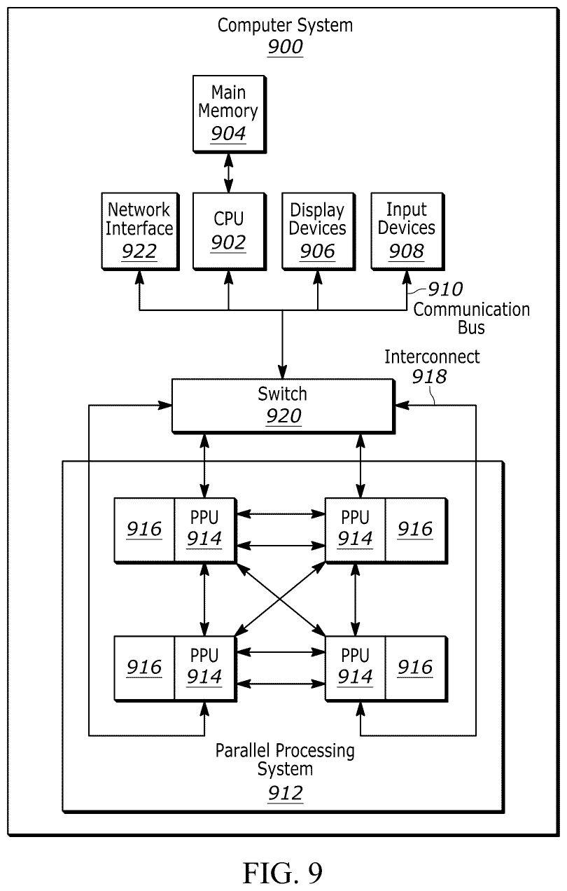

FIG. 9 illustrates a computer system 900, according to at least one embodiment. In at least one embodiment, computer system 900 is configured to implement various processes and methods described throughout this disclosure.

In at least one embodiment, computer system 900 comprises, without limitation, at least one central processing unit (“CPU”) 902 that is connected to a communication bus 910 implemented using any suitable protocol, such as PCI (“Peripheral Component Interconnect”), peripheral component interconnect express (“PCI-Express”), AGP (“Accelerated Graphics Port”), HyperTransport, or any other bus or point-to-point communication protocol(s). In at least one embodiment, computer system 900 includes, without limitation, a main memory 904 and control logic (e.g., implemented as hardware, software, or a combination thereof) and data are stored in main memory 904 which may take form of random access memory (“RAM”). In at least one embodiment, a network interface subsystem (“network interface”) 922 provides an interface to other computing devices and networks for receiving data from and transmitting data to other systems from computer system 900.

In at least one embodiment, computer system 00, in at least one embodiment, includes, without limitation, input devices 908, parallel processing system 912, and display devices 906 which can be implemented using a conventional cathode ray tube (“CRT”), liquid crystal display (“LCD”), light emitting diode (“LED”), plasma display, or other suitable display technologies. In at least one embodiment, user input is received from input devices 908 such as keyboard, mouse, touchpad, microphone, and more. In at least one embodiment, each of foregoing modules can be situated on a single semiconductor platform to form a processing system.

In at least one embodiment, computer programs in form of machine-readable executable code or computer control logic algorithms are stored in main memory 904 and/or secondary storage. Computer programs, if executed by one or more processors, enable system 900 to perform various functions in accordance with at least one embodiment. Memory 904, storage, and/or any other storage are possible examples of computer-readable media. In at least one embodiment, secondary storage may refer to any suitable storage device or system such as a hard disk drive and/or a removable storage drive, representing a floppy disk drive, a magnetic tape drive, a compact disk drive, digital versatile disk (“DVD”) drive, recording device, universal serial bus (“USB”) flash memory, etc. In at least one embodiment, architecture and/or functionality of various previous figures are implemented in context of CPU 902; parallel processing system 912; an integrated circuit capable of at least a portion of capabilities of both CPU 902; parallel processing system 912; a chipset (e.g., a group of integrated circuits designed to work and sold as a unit for performing related functions, etc.); and any suitable combination of integrated circuit(s).

In at least one embodiment, architecture and/or functionality of various previous figures are implemented in context of a general computer system, a circuit board system, a game console system dedicated for entertainment purposes, an application-specific system, and more. In at least one embodiment, computer system 900 may take form of a desktop computer, a laptop computer, a tablet computer, servers, supercomputers, a smart-phone (e.g., a wireless, hand-held device), personal digital assistant (“PDA”), a digital camera, a vehicle, a head mounted display, a hand-held electronic device, a mobile phone device, a television, workstation, game consoles, embedded system, and/or any other type of logic.

In at least one embodiment, parallel processing system 912 includes, without limitation, a plurality of parallel processing units (“PPUs”) 914 and associated memories 916. In at least one embodiment, PPUs 914 are connected to a host processor or other peripheral devices via an interconnect 918 and a switch 920 or multiplexer. In at least one embodiment, parallel processing system 912 distributes computational tasks across PPUs 914 which can be parallelizable—for example, as part of distribution of computational tasks across multiple graphics processing unit (“GPU”) thread blocks. In at least one embodiment, memory is shared and accessible (e.g., for read and/or write access) across some or all of PPUs 914, although such shared memory may incur performance penalties relative to use of local memory and registers resident to a PPU 914. In at least one embodiment, operation of PPUs 914 is synchronized through use of a command such as_syncthreads( ), wherein all threads in a block (e.g., executed across multiple PPUs 914) to reach a certain point of execution of code before proceeding.

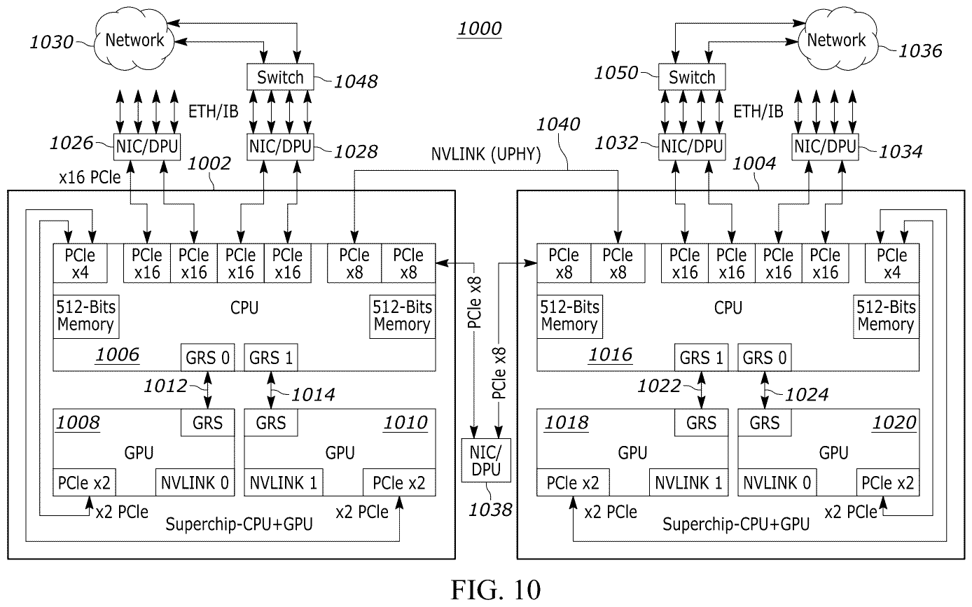

FIG. 10 is a block diagram that schematically illustrates a computing system 1000, e.g., a data center or a High-Performance Computing (HPC) cluster, in accordance with an embodiment that is described herein. System 1000 comprises a plurality of subsystems, e.g. multiple processing devices coupled to each other, multiple network devices, and multiple networks, according to at least one embodiment. Computing system 1000 is designed with multiple integrated circuits (referred to as processing devices), where each integrated circuit can include one or more CPUs and GPUs, forming a powerful and flexible architecture.

The various processing devices are interconnected via an NVLink or other high-speed interconnect, enabling high-speed communication between the subsystems, and are also connected through a network interface controller (NIC) or data processing unit (DPU) to ensure efficient data transfer across computing system 1000 and to one or more external networks 1030, 1036. In the present example, system 1000 comprises a packet switch 1048 that connects NIC/DPU 1028 to network 1030, and a packet switch 1050 that connects NIC/DPU 1032 to network 1036.

The coupling of processing devices through NVLink allows for seamless data exchange and parallel processing, enhancing overall computational performance. The processing devices are connected to multiple networks through one or more NICs or DPUs, enabling the system to handle complex, multi-network tasks with high bandwidth and low latency. This configuration is highly suitable for demanding applications that require significant processing power, such as artificial intelligence (AI), machine learning (ML), and data-intensive computing, while ensuring robust connectivity and scalability across various networked environments. The integrated circuits of the computing system 1000 can include one or more CPUs and one or more GPUs.

FIG. 10 also demonstrates an example architecture of a multi-GPU architecture. As illustrated in the figure, computing system 1000 includes a processing device 1002 with a multi-GPU architecture. In particular, processing device 1002 may be a system-on-chip and includes multiple subsystems such as a CPU 1006, a GPU 1008, and a GPU 1010. CPU 1006 can be coupled to GPU 1008 via a die-to-die (D2D) or chip-to-chip (C2C) interconnect 1012, such as a Ground-Referenced Signaling interconnect (GRS interconnect). CPU 1006 can be coupled to GPU 1010 via a D2D or C2C interconnect 1014. CPU 1006 can also couple to GPU 1008 and GPU 1010 via PCIe interconnects.

CPU 1006 can be coupled to one or more NICs or DPUs, which are coupled to one or more networks. For example, as illustrated in FIG. 10, CPU 1006 is coupled to a first NIC/DPU 1026, which is coupled to a network 1030. CPU 1006 is also coupled to a second NIC/DPU 1028, which is coupled to network 1030 via switch 1048. NIC/DPU 1026 and NIC/DPU 1028 can be coupled to network 1030 over Ethernet (ETH), NVLINK or InfiniBand (IB) connections, for example.

Computing system 1000 also includes a processing device 1004 with a multi-GPU architecture. In particular, processing device 1004 includes multiple subsystems including a CPU 1016, a GPU 1018, and a GPU 1020. CPU 1016 can be coupled to GPU 1018 via an D2D or C2C interconnect 1022. CPU 1016 can be coupled to GPU 1020 via a D2D or C2C interconnect 1024. CPU 1016 can also couple to GPU 1018 and GPU 1020 via PCIe interconnects. CPU 1016 can be coupled to one or more NICs or DPUs, which are coupled to one or more networks. For example, as illustrated in FIG. 3, CPU 1016 is coupled to a first NIC/DPU 1032, which is coupled to a network 1036 via switch 1050. CPU 1016 is also coupled to a second NIC/DPU 1034, which is coupled to network 1036. NIC/DPU 1032 and NIC/DPU 1034 can be coupled to network 1036 over Ethernet (ETH), NVLINK or InfiniBand (IB) connections.

In at least one embodiment, processing device 1002 and processing device 1004 can communication with each other via a NIC/DPU 1038, such as over PCIe interconnects. Processing device 1002 and processing device 1004 can also communicate with each other over a high-bandwidth communication interconnects 1040, such as an NVLink interconnect or other high-speed interconnects. The packet switches in FIG. 10 may comprise, for example, Nvidia Quantum-2 switches. The NICs/DPUs in the figure may comprise, for example, Nvidia Bluefield DPUs. In various embodiments, any of the network devices of system 1000, e.g., any of NICs/DPUs 1026, 1028, 1032, 1034 and 1038, and/or any of switches 1048 and 1050, may use a coupling mechanism in accordance with the techniques described herein.

Although the operations of the method(s) herein are shown and described in a particular order, the order of the operations of each method may be altered so that certain operations may be performed in an inverse order or so that certain operations may be performed, at least in part, concurrently with other operations. In another embodiment, instructions or sub-operations of distinct operations may be implemented in an intermittent and/or alternating manner.

Alternatively, embodiments of the disclosure may be implemented entirely in hardware or in an implementation containing both hardware and software elements. In embodiments which use software, the software may include but is not limited to firmware, resident software, microcode, etc.

Although specific embodiments of the disclosure have been described and illustrated, the disclosure is not to be limited to the specific forms or arrangements of parts so described and illustrated. The scope of the disclosure is to be defined by the claims appended hereto and their equivalents.

What is claimed is:

1. An apparatus comprising:
a printed circuit board (PCB);
a top cover at a top surface of the PCB;
a bottom plate at a bottom surface of the PCB; and
at least one coupling mechanism that includes a captive screw and a spring around the captive screw, wherein the at least one coupling mechanism is configured to;
press the top cover, the PCB, and the bottom plate together; and
expose threads of the captive screw at the bottom plate for attachment to a base board.

2. The apparatus of claim 1, wherein the captive screw passes through an opening in the top cover, an opening in the PCB, and a treaded opening in the bottom plate.

3. The apparatus of claim 1, wherein the top cover includes an opening, the opening in the top cover having a first portion and a second portion, wherein:
a diameter of the first portion of the opening is greater than a diameter of the second portion of the opening;
the opening in the top cover includes a spring hard stop at a transition between the first portion of the opening and the second portion of the opening;
the diameter of first portion of the opening accommodates a shank of the captive screw and the spring; and
the diameter of the second portion of the opening accommodates the shank of the captive screw but not the spring.

4. The apparatus of claim 1, wherein the at least one coupling mechanism includes four coupling mechanisms.

5. An apparatus comprising:
a printed circuit board (PCB);
a bottom plate at a bottom surface of the PCB;
a top cover at a top surface of the PCB; and
at least one captive screw having a screw head, a shank, and threads; and
at least one spring around the shank of the captive screw;
the top cover including an opening having a first portion and a second portion, wherein a diameter of the first portion of the opening is greater than a diameter of the second portion of the opening, and wherein the diameter of first portion of the opening accommodates the shank and the spring and the diameter of the second portion of the opening accommodates the shank but not the spring;
the bottom plate including a threaded opening wherein the threads of the captive screw mate with the threaded opening of the bottom plate; and
the captive screw positioned within the opening of the top cover, within an opening in the PCB, and within the threaded opening of the bottom plate.

6. The apparatus of claim 5, wherein the opening in the top cover includes a spring hard stop at a transition between the first portion of the opening and the second portion of the opening.

7. The apparatus of claim 5, wherein the diameter of the first portion of the opening in the top cover matches a diameter of the spring.

8. The apparatus of claim 5, wherein:
the opening in the top cover includes a spring hard stop at a transition between the first portion of the opening and the second portion of the opening; and
the diameter of the first portion of the opening in the top cover matches a diameter of the spring.

9. The apparatus of claim 5, wherein the opening in the top cover includes a screw head hard stop that extends from a top surface of the top cover and that is configured to abut the screw head of the captive screw.

10. The apparatus of claim 5, wherein:
the opening in the top cover includes a spring hard stop at a transition between the first portion of the opening and the second portion of the opening;
the diameter of the first portion of the opening in the top cover matches a diameter of the spring; and
the opening in the top cover includes a screw head hard stop that extends from a top surface of the top cover.

11. The apparatus of claim 5, wherein the threads of the captive screw are configured to attach to a base board.

12. The apparatus of claim 5, wherein the shank of the captive screw includes a first portion and a second portion, wherein:
a diameter of the first portion of the shank is greater than a diameter of the second portion of the shank; and
the first portion of the shank is about a third of the length of the shank and the second portion of the shank is about two-thirds of the length of the shank.

13. The apparatus of claim 5, wherein the threads have a length of about 1.5-2.5 mm.

14. The apparatus of claim 5, wherein the shank of the captive screw includes a first portion and a second portion, wherein:
a diameter of the first portion of the shank is greater than a diameter of the second portion of the shank;
the first portion of the shank is about a third of the length of the shank and the second portion of the shank is about two-thirds of the length of the shank; and
the threads have a length of about 1.5-2.5 mm.

15. The apparatus of claim 5, wherein:
the opening in the top cover includes a spring hard stop at a transition between the first portion of the opening and the second portion of the opening;
the diameter of the first portion of the opening in the top cover matches a diameter of the spring; and
the shank of the captive screw includes a first portion and a second portion, wherein the first portion of the shank is about a third of the length of the shank and the second portion of the shank is about two-thirds of the length of the shank.

16. An apparatus comprising:
a captive screw for a printed circuit board (PCB) module that includes a PCB, a bottom plate, and a top cover, the captive screw including;
a screw head;
a shank configured to pass through an opening in the top cover and an opening in the PCB, and having a first portion with a first diameter and a second portion with a second diameter, wherein the first diameter is greater than the second diameter; and
threads, wherein the threads are configured to mate with threads of an opening in the bottom plate and to engage a base board upon passing through the opening in the bottom plate.

17. The apparatus of claim 16, wherein the first portion of the shank is about a third of the length of the shank and the second portion of the shank is about two-thirds of the length of the shank.

18. The apparatus of claim 16, wherein the threads have a length of about 1.5-2.5 mm.

19. The apparatus of claim 16, wherein:
the first portion of the shank is about a third of the length of the shank and the second portion of the shank is about two-thirds of the length of the shank; and
the threads have a length of about 1.5-2.5 mm.

20. The apparatus of claim 16, wherein the shank includes a spring attachment feature.
